(19) United States
(12) Patent Application Publication
(10) Pub. No.: US 2021/0126211 A1
(43) Pub. Date: Apr. 29, 2021

(54) ETCHED SILICON BASED DEVICES AND METHODS FOR THEIR PREPARATION

(71) Applicant: B.G. NEGEV TECHNOLOGIES AND APPLICATIONS LTD., AT BEN-GURION UNIVERSITY, Beer-Sheva (IL)

(72) Inventor: Muhammad Y. BASHOUTI, Sde Boker (IL)

(21) Appl. No.: 16/965,344

(22) PCT Filed: Jan. 31, 2019
(86) PCT No.: PCT/IL2019/050120

§ 371 Date: Jul. 28, 2020

Related U.S. Application Data
(60) Provisional application No. 62/624,132, filed on Jan. 31, 2018.

(51) Int. Cl. H01L 51/42; H01L 51/00

(52) U.S. Cl. CPC H01L 51/4266; H01L 51/0017; H01L 51/0015; H01L 51/002; H01L 51/0002

(57) ABSTRACT

A device for converting radiation to electrical energy having a hybrid interface structure comprising an etched silicon surface and organic layer connected thereto. The invention provides methods for the preparation of said etched silicon surface and said hybrid interface.

### BACKGROUND OF THE INVENTION

In recent years, solar cells have attracted growing interest for applications in renewable energy technology due to rising concerns about climate change and the sustainability of fossil fuels. Silicon (Si) has been investigated as potential candidate for next-generation solar cells because of its efficient light harvesting and carrier collection capability. However, solar cells based on Si (especially nano Si) require energy-intensive semiconductor processes, including high-temperature thermal diffusion, thermal annealing of the electrodes and high-vacuum chemical deposition processes, all of which increase the fabrication costs of Si based solar cells systems.

Thin film solar cells are more cost-effective than bulk silicon based cells, however, it is known that the reported experimental efficiencies of nano Si based solar cells remain significantly lower than their estimated theoretical efficiency, as well as the efficiency of conventional Si solar cells. One of the reasons for the decreased efficiency arises from the processing and fabrication methods utilized in thin film technologies, which require overcoming fundamental material-based limitations in order to unlock the full efficiency and cost saving potential of the different technologies.

One known material-based limitation related to Si is the SiO₂ layer. The Oxide layer is characterized by having a low carrier mobility, typically ranging between 5-18 cm²V⁻¹S⁻¹, due to a high number of unwanted, uncontrolled interface states included in the band gap. The oxide layer comprises Si—O bonds, which are known to introduce surface states into the band gap, increase the recombination rate and decrease the solar cell overall performance. In addition, Si—O bonds decrease the stability of surficial bonds. Therefore, eliminating such Si—O bonds is beneficial in terms of improving charge carrier mobility from the medium in which charge separation takes place, which is commonly an organic based polymer, to the silicon substrate for energy harvesting process. Moreover, the efficiency of the light harvesting process greatly depends on the distance between the organic-based polymer and the silicon substrate, therefor the geometry and architecture of the junction play an important role and effects the overall performance of the system. Regarding the effect of geometry on the overall performance of silicon-based photovoltaic cells, one should note that while increasing the surface area of the silicon allows a more efficient absorbance of the incoming light, it will also lead to a higher surface recombination and often higher junction area which results in electrical charge degradation.

Therefore, there is a need for a light harvesting device having an efficient Si-organic junction, and facile methodology to overcome the unfavorable tradeoff concerning the cell geometry, which allows the fabrication of an efficient device in an easy and low cost manner.

### SUMMARY OF THE INVENTION

The present invention provides a method for preparing a silicon hybrid interface structure comprising the following steps: Providing an etched Si substrate having Si—H bonds on the surface; a) Exposing the silicon surface of step (a) to chlorine containing gas while illuminating the surface with light; and b) treating the Si substrate of step (b) with one or more organic reactant(s) to produce a first organic layer which is covalently bonded to the silicon surface. The Si substrate which is provided in step (a) is an etched silicon substrate characterized in having a nanowire (NW) morphology.

The substrate of step (a) is provided by an etching procedure comprising the steps of: subjecting an H-terminated Si surface to a solution comprising an oxidizable aggregation agent and an acid, oxidizing the surface to remove aggregated material formed on the Si substrate and washing said surface.

The etching procedure of the invention is preceded by and followed by a surface treatment comprising the steps of a) removal of Si-oxide layer with the aid of HF/NH₄F solution, b) thermally growing a fresh Si-oxide layer and c) removal of said freshly grown Si-oxide layer to obtain H-terminated Si surface.

The organic reactants utilized for the first organic layer are selected from the group consisting of amine, alcohol, halide and alkylating reagent. These reactants are characterized in having at least one functional groups, such that said group reacts with the Si surface atom/s.

The present invention further comprising the step of reacting the Si surface having the first organic layer thereon with a second organic reactant to provide a second functional layer, said second organic layer is either covalently bound or physically adsorbed to the first organic layer.

The present invention further provides a method for the preparation of etched silicon substrate having nanowires morphology comprising the steps of: (a) providing a hydrogen terminated silicon substrate; (b) exposing the substrate obtained in step (a) to an oxidizable aggregation agent and an acid; (c) oxidizing the surface to remove aggregated material formed on the Si substrate; and (d) washing the silicon substrate obtained in step (c) to remove residual aggregation reagent from said surface. This etching procedure is preceded by and followed by a surface treatment comprising the steps of a) removal of Si-oxide layer with the aid of HF/NH₄F solution, b) thermally growing a fresh Si-oxide layer and c) removal of said freshly grown Si-oxide layer to obtain H-terminated Si surface.

The present invention further provides a device for converting radiation to electrical energy having a hybrid interface structure. The device of the invention comprises i) An etched Si substrate and an organic layer coating said Si substrate, where said etched Si substrate is substantially free of Si—O bonds.

### DESCRIPTION OF THE INVENTION

One aspect of the invention is a method for preparing a silicon hybrid interface structure comprising the following steps: Providing Si substrate having Si—H bonds on the surface; Exposing the silicon surface of step (a) to chlorine gas while illuminating the surface with light; and treating the Si substrate of step (b) with organic reactants to produce a first organic layer which is covalently bonded to the silicon surface.

Si substrate having Si—H bonds on the surface is preferably prepared by removing an oxide layer that is present on a silicon substrate, followed by surface etching. That is, the present invention provides a hybrid junction, instead of utilizing silicon oxide which is characterized in low carrier mobility, high recombination rate and decrease stability of surficial bonds of silicon oxide. Thus, the present invention provides a method for replacing the oxide terminated silicon surface with a silicon functionalized with at least one organic layer. According to the principles of the present invention, an etching process takes place before the grafting of the organic layer. The steps of oxide layer removal and etching are now described in more detail.

### Oxide Layer Removal

According to some embodiments, the Si substrate sought to be treated is cleaned by applying alcohol to the surface and optionally sonicating the Si substrate in said alcohol. In some embodiment said alcohol is isopropanol. In further embodiments, the cleaned surface is dried under inert gas flow, e.g. nitrogen gas. According to the principles of the invention, the Si surface/substrate used in the present invention is a silicon wafer, i.e. a thin slice of crystalline silicon, having the crystalline orientation of <112> with main facets of (100) and (111).

According to the principles of the present invention, growing of surface oxide layer and the removal of said layer takes place in a controlled manner to allow a reproducible fabrication process and to promote a stable hydrogen-terminated Si surface, a) before chemically etching the silicon surface (pre-etching) and b) before grafting of the at least one organic layer. Thus, in some embodiments, the present invention provides the following steps for the preparation of oxide-free Si substrate: (1) the Si substrate is being subjected to HF solution and then to NH₄F solution, followed by rinsing the substrate with water and drying under nitrogen flow. (2) the clean surface obtained from step (1) is being thermally oxidized under oxygen gas at high temperature of between about 300° C. to about 600° C. and relative humidity ranging between about 10% to about 60%. (3) the oxide layer obtained in step (2) is removed by repeating step (1). (4) the hydrogen-terminated Si surface obtained in step (3) is being situated under vacuum in order to remove residual solvents.

The obtained surface is free of Si—O bonds as can be detected in XPS, and is kept under inert conditions for further processing.

In some embodiments, the oxidation of step (2) is carried out at a temperature ranging from about 350° C. to about 550° C., from about 400° C. to about 550° C. or at about 500° C. Each possibility represents a separate embodiment of the invention.

In some embodiments, the oxidation of step (2) is carried out in a relative humidity of between about 20% to about 50%, from about 25% to about 40% or at about 30% relative humidity. Each possibility represents a separate embodiment of the invention.

### Surface Etching

According to some embodiments, the present invention further provides a unique etching process promoting the formation of an etched, defect-free, hydrogen-terminated Si surface. The process takes place in a few sequential stages and involves the formation of nanoparticles (or aggregates) on the silicon surface, followed by the removal of these particles together with surface Si atoms which were in close proximity to said aggregates, providing an etched silicon surface morphology. The obtained etched morphology appears as elongated nanowires of silicon, which are formed by the removal of said nanoparticles from the silicon surface together with the silicon surface atoms. According to some embodiments, the etching process comprises the following steps: (a) hydrogen terminated silicon substrate is being subjected to an oxidizable aggregation agent and an acid ; (b) oxidizing the surface to remove aggregated material formed on the Si substrate; (c) washing the silicon substrate obtained in step (b) to remove residual aggregation agent (catalyst) from said surface.

According to some embodiments, the aggregation agent utilized in step (a) of the surface etching process as described above, is selected from the group consisting of silver nitrate (AgNO₃), Polystyrene, chloroauric acid (HAuCl₄), silver acetate (AgCO₂CH₃), silver benzoate (AgCO₂C₆H₅), Iron(II) acetate, Iron(III) chloride, Fe(NO₃)₃, Ag (s), Au (s), Pt (s), Cr(s) and tetramethylammonium hydroxide. Each possibility represents a separate embodiment of the invention. According to some currently preferred embodiments, the aggregation agent utilized in step (a) is silver nitrate (AgNO₃).

In some related embodiments, the acid utilized together with the aggregation agent in step (a) of the surface etching process is selected from the group consisting of NH₄F, NH₄OH, mixture of HF:NH₄F and H₂ by gassing.

In some currently preferred embodiment, the acid utilized in step (a) together with the aggregation agent is HF. In some specific embodiments, the aggregation agent utilized in step (a) is AgNO₃ together with the acid HF.

In some embodiments, the concentration of the aggregation agent solution utilized for step (a) is between about 0.01M to about 0.1M. In some other embodiments, the concentration of the aggregation agent solution is between about 0.01M to about 0.05M. In some currently preferred embodiment, the concentration of the aggregation agent solution utilized in step (a) is about 0.02M. In some currently preferred embodiments, the aggregation agent solution utilized in step (a) is 0.02M AgNO₃ solution.

In some embodiments, the concentration of the acid solution utilized for step (a) is between about 1M to about 10M. In some embodiments, the acid concentration is between about 3M and 7M, 4M to 6M or about 5M acid solution. In some currently preferred embodiments, the acid solution utilized in step (a) is 5M HF solution.

In some related embodiments, the volume ratio of the aggregation agent solution to acid solution is about 1:20, about 1:15, about 1:10, about 1:5, respectively. In some currently preferred embodiments, the aggregation solution comprises 0.02M AgNO₃ solution and a 5M HF solution in a ratio of about 1:10, respectively.

In some embodiments, the mixture utilized in step (b) is a mixture of between about 5% to about 50% H₂O₂ and between about 1M to about 8M HF solution in a volume ratio of between about 1:10 to about 10:1, respectively. In some currently preferred embodiments, the mixture utilized in step (b) is a mixture of between 30% H₂O₂ solution and 5M HF solution at a volume ratio of about 1:1. In further related embodiments, the mixture utilized in step (b) is a mixture of between about 5% to about 50% H₂O₂ and between about 1M to about 8M NH₄OH solution in a volume ratio of between about 1:10 to about 10:1, respectively. In some currently preferred embodiments, the mixture utilized in step (b) is a mixture of between 30% H₂O₂ solution and 5M NH₄OH solution at a volume ratio of about 1:1. In some related embodiments, the mixture utilized in step (b) contains between about 1 to 50 wt % HF. According to certain embodiments, the nitric acid solution utilized in step (c) is a 70 wt % solution.

Without being bound by theory or mechanism of action, it is postulated that the H₂O₂ contacting in step (b) forms a thermodynamically unstable intermediate compound AgO(OH) which functions as an efficient oxidant. The Si atoms situated below the Ag nanoparticles (originating from the aggregation agent) are being removed upon contact with HF which give rise to the etched Si morphology. Furthermore, the present invention promotes the ability to fine-tune the resulted etched surface properties (porosity, surface reflectance, wettability, work-function), by modifying the conditions and duration of the above mentioned steps. Step (a) can be tuned to modify the porosity of the obtained etched silicon substrate, i.e. by changing the concentration of the oxidaizable aggregation agent utilized in step (a), where a high concentration of particles on the surface sought to be etched will promote greater porosity in the final product. Another way to fine-tune the system of the invention is to utilize step (b) and change the duration of the obtained aggregate-decorated silicon surface exposure to the acidic solution. The latter was found by the inventors to have a direct effect on the obtained nanowires structure, the longer the time of exposure—the longer the silicon nanowire structure obtained from the process (as can be detected in FIG. 6). However, overly coated Si surface with Ag particles might cause difficulties at a later stage as the etching solution containing H₂O₂ would not be able to contact the Si surface. In order to avoid the full coating by the silver particles, a diluted Ag solution of less than 1M is being used, and also a short exposure time of the silicon surface to the Ag solution of less than 60 seconds is commonly used.

The present invention's etching process is anisotropic and follows certain crystal orientations and demonstrates temperature dependency.

The resultant etched Si substrate is being treated again according steps 1 to 3 as described above in order to regain the fully hydrogen-terminated surface (post-etching), schematically illustrated in FIG. 1.

It is important to note that the etching process of the invention provides the ability to control the porosity and the reflectivity degrees of the etched Si as a function of the etching time as can be seen in FIG. 5. The reflectivity was measured at 600 nm as an example for the whole visible spectrum as appeared in FIG. 5B.

Without being bound by any mechanism of action or theory, it is postulated that silicon substrate doping level has an effect on the ability to grow the silicon nanowires and achieve the etched surface morphology of the invention as described above. It is further postulated that upon utilizing n-doped silicon substrate the preferred dopant concentration allowing the beneficial nanowire growth according to the principles of the invention is between about n=10¹⁵ cm⁻³ to about 10¹⁶ cm⁻³. Additionally, upon utilizing p-doped silicon substrate, the preferred dopant concentration allowing the beneficial nanowires growth according to the principles of the invention is between about p=10¹⁷ cm⁻³ to about p=10¹⁷ cm⁻³.

### Surface Chlorination and Organic Layer Grafting

According to the present invention, small molecules are now grafted to form an organic layer over the etched silicon surface. This is carried out via forming covalent bonds between the organic molecules and surface Si atoms of the etched silicon surface of the invention. In order to maintain a reproducible process and to eliminate surface contaminations or silicon oxide formation, the grafting of the organic layer takes place utilizing anhydrous organic solvents and under inert conditions. In some embodiments, the grafting of organic layer to the etched Si surface takes place in a nano-reactor. In some related embodiments, the grafting is carried out utilizing shock waves in order to overcome surface forces.

The formation of the organic layer may take place in a single step, which includes exposing the hydrogenated Si surface to the desired reactants to promote the chemical bonding between Si surface atoms and the active organic compound to form a layer of said active organic compound. In another embodiment, the formation of the organic layer may take place in two steps creating two layers: i) coating the etched Si surface with passive organic molecules (first layer—which is covalently bound to the silicon surface); and ii) optionally functionalizing the layer obtained in step (i) with active molecules, where the molecules in the first layer serve as linkers between the Si surface and the active molecules in the second layer. It should be understood that in case that the grafting process takes place in a single step, the single layer comprising the active organic molecules is deposited under the same conditions as utilized for the deposition of the first layer in the two step process. Thus, the step of exposing hydrogenated Si surface to organic reactant is carried out under the same conditions whether the reactant is a passive or active organic molecule. As used herein and in the claims, the term “organic compound” or “organic molecule” is used interchangeably with the term “organic reactant”.

According to the principles of the present invention, the method for grafting the first organic layer to the etched Si surface comprises the steps of: (a) subjecting the hydrogen-terminated etched Si surface to chlorine containing gas (chlorination) and to light illumination; (b) treating the obtained chlorinated Si surface achieved in step (a) with organic reactants/molecules thereby producing a first organic layer onto the Si substrate. In some embodiments, the organic reactant/compound is selected from the group consisting of alkylation agent, amine, alcohol and combinations thereof; the term “alkylating agent” as used herein and in the claims refers to an agent which enable a covalent addition of carbon based chain, which may be saturated or unsaturated chain. In some embodiments, the reactants utilized for the preparation of the first organic layer which is chemically bound to the etched Si substrate are characterized in having at least two functional groups, such that at least one group reacts with the surface Si atom/s and the second group is available for further functionalization. Therefore, said first organic layer may serve as a linker between the Si surface and a second organic layer which may be deposited onto said first layer. According to some embodiments, a second organic layer is deposited on the first organic layer, said second layer is composed out of reactants that are chemically bound through the available functional group of the first organic layer. Thus, the grafting process comprises the optional step (c) the Si surface resulted in step (b) is further functionalized with organic compound/reactant thereby obtaining a second organic layer which is chemically bound to the first organic layer.

In some other embodiments, the reactants utilized for the preparation of the first organic layer which is chemically bound to the etched Si substrate are characterized in having only one functional group, said group reacts with the surface Si atom/s and to form covalently bonded first organic layer on the silicon surface. In these embodiments, the optionally grafted second organic layer is attached to the first organic layer via physical adsorption (including electrostatic adsorption) and not via covalent bonding. Said physically adsorbed second organic layer can be grafted on the covalently bound first organic layer utilizing Langmuir Blodgett methods or by drop casting methods.

In should be understood that in any case, the organic layer which is in contact with the surface silicon atoms (the base layer) is always covalently bound to it in order to allow the stable junction of the invention and in order to prevent the oxidation of silicon surface atoms and the formation of the unfavorable silicon oxide species. However, the second layer (the top layer), if exists, can be either covalently bound or physically attached to the base layer.

In some embodiments, the first or the second layer are composed of active organic compounds/reactants selected from chemically active and optically active compounds.

In some embodiments, the chlorine gas mixture or the chlorine gas containing mixture utilized in step (a) is Cl₂/N₂. In some embodiments, the mixture comprising between about 0.1% Cl₂ about 1% Cl₂ and between about 99.9% N₂ to about 99.0% N₂, respectively. In some currently preferred embodiments, the mixture comprising 0.4% Cl₂ and 99.6% N₂.

In some embodiments, the light in step (a) is a visible light. In some embodiments, the intensity of the visible light illumination applied in step (a) is between about 0.1 mW to about 30 mW. In some specific embodiments, the intensity of visible light irradiation applied in step (a) is about 5 mW. In some embodiments the illumination is carried out at a wavelength of between about 400 nm to 600 nm. In some other embodiments, the illumination is carried out at a wavelength of between about 400 nm to 500 nm. In some specific embodiments, the illumination is carried out at a wavelength of about 470 nm.

In some embodiments, the organic compound utilized in step (b) forms C—Si bond with the etched silicon surface of the invention utilizing a Grignard regent. In some embodiments, the organic compound utilized in step (b) give rise to R—Si bond wherein R is an alkyl of the form —CₙH₂ₙ₊₁ and n in an integer from 1 to 6. In some other embodiments, R is an alkene of the form —CₙH₂ₙ wherein n in an integer from 1 to 6. In some other embodiments, R is an alkyne of the form —CₙH₂ₙ₋₂ wherein n in an integer from 1 to 6. In some related embodiments, the Si—C bond forms by an Alkyl-CₙH₂ₙ₊₁ such as methyl, ethyl, propyl, etc.), CₙH₂ₙ (such as 1-octene, 1-pentene, 1-dodecene, 1-octadecene), and alkynes-CₙH₂ₙ₋₂ (such as 1-pentyne, 1-dodecyne, 2-hexyne). In some other embodiments, the chemical bond to the etched Si surface occurs through a Si—C—C bond, Si—C═C bond, or Si—C≡C bond. Without being bound by any theory or mechanism of action, it is postulated that for the Si—C—C bond, the charge transfer will be relatively low compared with the Si—C═C and Si—C≡C bonds.

In certain embodiments, the organic compound utilized in step (b) forms N—Si bond with the etched silicon surface of the invention. In some related embodiments, the organic compound utilized is of the form R—NH₂ wherein R is CₙH₂ₙ₊₁ and n is an integer from 1 to 6.

In certain embodiments, the organic compound utilized in step (b) forms O—Si bond with the etched silicon surface of the invention utilizing radiation or heating during the reaction. In some related embodiments, the organic compound utilized is of the form R—OH wherein R is CₙH₂ₙ₊₁ and n is an integer from 1 to 6.

In certain embodiments, the organic compound utilized in step (b) forms X—Si bond with the etched silicon surface of the invention, wherein X is a halide selected from the group consisting of X═H, F, Cl, Br and I.

The grafting process of the present invention results in a molecular coverage of the etched silicon surface such that the grafting covers between about 50% to about 100% of the Si surface. In a currently preferred embodiment, the grafted molecules cover between about 80% to about 100% of the Si surface.

In some embodiments, the second layer optionally deposited on the etched Si substrate of the invention is chemically bonded to the first layer described above. In some other embodiments, the second organic layer optionally deposited on the etched Si substrate of the invention is adsorbed to the surface and is in direct contact with the first organic layer. The organic compounds which are utilized for the formation of such second layer described as step (c), can be functional electrical molecules (such as n-type molecules, p-type molecules), optically active molecules and combination thereof. It should be understood that in the case where the grafting takes place in a single step, the deposited active organic layer comprises functional electrical molecules such as n-type molecules, p-type molecules, optically active molecules and combination thereof.

In some embodiments, the reactant utilized for step (c) or for the single step grafting process, comprises functional electrical molecules for n-type doping (active n-type compounds). In some embodiments, the electrical molecules for n-type doping are selected from the group consisting of: CoCp₂ [Bis (cyclopentadienyl) cobalt(II), Eᵢ=3.3 eV], Cr(bpy)₃ [Tris(2,2′-bipyridine) chromium, Eᵢ=3.14 eV], Cr (TMB)₃ [Tris (4,4′,5,5′-tetramethyl-2,2′-bipyrdine) chromium, Ei=2.85 eV], Ru(terpy)₂ [Bis(2,2′,6′,2″-terpyridine]ruthenium, Eᵢ=3 eV], M₂(hpp)₄ wherein M is Cr or W. For example, Tetrakis[μ-(1,3,4,6,7,8-hexahydro-2H-pyrimido[1,2-α]pyrimidinto]ditungesten, Eᵢ=3 eV. In some currently preferred embodiments, the electrical molecules for n-type doping are selected from CoCp₂ and Cr(TMB)₃.

In some embodiments, the active organic compounds utilized for step (c) or for the single step grafting process, comprises functional electrical molecules for p-type doping (active p-type compounds). In some embodiments, the electrical molecules for p-type doping are selected from the group consisting of: ethylene glycol, DMSO, PSS-PEDOT polymer, CBP [4,4′-bis(carbazol-9-yl)-2,2′-biphenyl, Ei=6.00 eV], α-NPD [N,N′-diphenyl-N,N′-bis(1-naphthyl)-1,1′-biphenyl-4,4′-diamine, Ei=5.35 eV], CN6-CP[Hexacyano-trimethylene-cyclopropane, Ei=5.8 eV], Pentacene, Ei=5.5 eV, Quinacridone, Ei=5.4 eV, Metal phthalocyanines, Ei=˜6.5 eV (depends on the metal ion), TCNQ (7,7,8,8-Tetracyanoquinodimethane) and fluorine derivative thereof (7.83 eV) and NDI [1,4,5,8-naphthalenediimides, Ei=5.5 eV (depends on the core substitution)]. In some currently preferred embodiments, the electrical molecules for p-type doping are selected from CBP and TCNQ.

In some embodiments, the active organic compounds utilized for step (c) or for the single step grafting process, comprises optically active molecules. In some other embodiments, the optically active molecules are selected from the group consisting of photoisomers and photo luminescent molecules. For example, azo-benzene compound going through photoisomerization from cis to trans conformation at 380 nm and trans to cis at 450 nm.

In some related embodiments, the optically active molecules are photo luminescent molecules. In some related embodiments, the photo luminescent molecules are selected from the group consisting of Si-(4-(Dicyanomethylene)-2-methyl-6-(4-dimethylaminostyryl)-4H-pyran, Si-Anthracene/Pyrene, Si-Tris(8-hydroxyquinolinato)aluminium (Alq₃) and derivatives thereof.

In some embodiments, the electrically active compounds are grafted onto a first layer having C—Si bond with the etched Si surface of the invention. In some other embodiments, the photoisomeric molecules are grafted onto a first layer having Si—N bonds with the etched Si surface of the invention. In some other embodiments, the photoluminescent molecules will be grafted onto a first layer having Si—O bonds with the etched Si surface of the invention.

In some optional embodiments, the active organic molecules comprising the functional electrical molecules for p-type doping, n-type doping or optically active molecules as described above are deposited as the first organic layer, directly onto the ached Si substrate. In such cases, the active organic reactants/compounds have a single functional group utilized for bonding to the Si atom of the etched surface.

In another aspect, the present invention provides a device for converting radiation to electrical energy having a hybrid interface structure comprising an etched Si substrate of the invention; and an organic layer; wherein said etched Si substrate surface is coated with said organic layer, and wherein said etched Si substrate is free of silicon oxide.

In some embodiments, the device of the invention comprises a functionalized Si surface, characterized in having organic molecules which are chemically bound to its surface.

Is some other embodiments, the device comprises the etched silicon surface of the invention, coated with a first layer (a bottom layer), which is covalently bound to the surface, and a second layer (top layer), which coats the first bottom layer. The second layer is either covalently bound to the first layer of physically attached to it.

In some embodiments, the organic reactant utilized to functionalize the etched Si surface comprises the compounds selected from: hydrocarbon having up to 6 carbon atoms, amine, alcohol, halide, sulfoxide, Bis (cyclopentadienyl) cobalt(II), Cr(bpy)₃ [Tris(2,2′-bipyridine) chromium, Cr(TMB)₃ [Tris (4,4′,5,5′-tetramethyl-2,2′-bipyrdine) chromium, Ru(terpy)₂ [Bis(2,2′,6′,2″-terpyridine]ruthenium, M₂(hpp)₄ wherein M is Cr or W, Tetrakis[μ-(1,3,4,6,7,8-hexahydro-2H-pyrimido[1,2-α]pyrimidinto]ditungesten, PSS-PEDOT polymer, CBP [4,4′-bis(carbazol-9-yl)-2,2′-biphenyl, α-NPD [N,N′-diphenyl-N,N′-bis(1-naphthyl)-1,1′-biphenyl-4,4′-diamine, CN6-CP [Hexacyano-trimethylene-cyclopropane, Pentacene, Quinacridone, Metal phthalocyanines, TCNQ (7,7,8,8-Tetracyanoquinodimethane) NDI 1,4,5,8-naphthalenediimides, Si-(4-(Dicyanomethylene)-2-methyl-6-(4-dimethylaminostyryl)-4H-pyran, Si-Anthracene/Pyrene, Si-Tris(8-hydroxyquinolinato)aluminium and combinations thereof.

The term “Si substrate” or “silicon wafer” as appear through the application and in the claims refer to the silicon surface on which the unique nanowires morphology is obtained utilizing the etching process of the invention and further can be functionalized with organic molecules according to the grafting procedure of the invention.

The term “nanowires” (NW) as used herein and in the claims refers to the morphology achieved by the etching process of the invention. Said structure is characterized in having elongated tubular structure, which are formed by the removal of silicon atoms from a silicon substrate in a vertical manner, utilizing a surface catalyst an acid as described in the etching procedure hereinabove.

The term “shock wave” as appear herein and in the claims refers to a disturbance occurring when applying high pressure of about 3 atm or more for a short time period in the range of several seconds of each occurrence. The shock wave is being utilized in order to overcome surface forces and facilitate the grafting process of the invention.

The term “hybrid interface structure” or “hybrid junction” as appear herein and in the claims refers to a silicon substrate (an inorganic material) which is covalently bonded to an organic molecule/moiety.

The term “unpure silicon” as appear herein and in the claims refers to silicon doped with industrial impurities for example, metals (such as gold). The impurities in said unpure silicon are present in a concentration of between about 10¹⁵ to about 10¹⁷ cm⁻³.

The term “substantially free of Si—O bonds” as appear herein and in the claims refers to that the silicon surface coated by the organic layer of the invention is characterized by having less than 5% Si—O bonds originating from a silicon oxide moiety on the silicon surface according to an XPS analysis.

### DESCRIPTION OF THE FIGURES

FIG. 1 represents schematic diagram of pre-etching, etching and post etching processes. The pre-etching and post etching are identical, and are meant to remove any Si—O bond from the Si surface. The exemplary schematic etching process based on three solutions: solution I is based on AgNO₃/HF, solution II is based on H₂O₂/HF and solution III is based on HNO₃.

FIG. 2 represent a schematic illustration of the silicon structure and chemical connectivity of a single silicon nanowire before and after the post-etching step.

FIG. 3 (A) depicts SEM image of the etched Si surface. (B) Schematic image for changing the refractive index gradually from 1 to 3.5.

FIG. 4 Raman (A) and reflection (B) spectra of etched and non-etched (normal) Si surface, demonstrating the increase in the absorption coefficient of etched Si (1-2 μm) relative to the normal Si i.e. bulk silicon (35%). The reflectivity of the etched Si decreased below 10% i.e. the etched Si can absorb most of the incident light, more than 90%.

FIG. 5 (A) Porosity of the etched Si as a function of etching time, (B) Reflectivity measured at λ=600 nm as function of the etching time.

FIG. 6 depicts the correlation between duration of exposure to 2 wt % HF (solution II of the etching process) to the length of the fabricated nanowires obtained in said process. (A) SEM side view images of different times of exposure. (B) graph summarizing the correlation between the NW length and acid exposure duration.

FIG. 7 demonstrates a schematic representation of the grafting of first layer (passive) molecules through different Si—X bonds, where X is C, N, or O. The grafting of the passive molecules is taking place on an etched silicon substrate, and the illustration includes the surface treatment as described in Example 1.

FIG. 8 demonstrates a schematic representation of Grafting of active functional molecules. Some possible active functional molecules: (a) Electrical active molecule: Charge transfer from the cobaltocene to the etched Si. (b) Photoisomer: the optical active molecule (Azobenzene) grafted though Si—N bonds. (c) Photoluminescence: the optical active molecule-4-(Dicyanomethylene)-2-methyl-6-(4-dimethylaminostyryl)-4H-pyran will emit a red light.

FIG. 9 depicts the XPS characterization of silicon surfaces after different stages of functionalization. (A) comparison between fully functionalized silicon surface having organic layer deposited on its surface (a), silicon after pre-etching process (b) and an untreated silicon surface (c). (B) deconvoluted XPS C1s peak comparing the contribution of different carbon bonds in a silicon sample before organic layer grafting (top) and after grafting (bottom).

FIG. 10 (A) depicts photoelectron yield Y(hv) versus photon energy for etched Si before and after organic layer grafting. The organic layer grafted on the Si surface is methyl. (B) J-V curve of etched Si before (open squares, oxide layer) and after (filled squares, organic layer) organic layer grafting. The organic layer grafted on the Si surface is methyl. Inset: top view of etched Si solar cell device structure. (C) Energy diagram of the etched Si interface in thermal equilibrium. The arrows indicate different magnitude of hole injection from the etched n-Si into the p-type. On the left injection from Si oxide to PEDOT:PSS and on the right from Si covered with methyl (no oxide layer) into PEDOT:PSS. The reduction of surface state density Dᵢₜ as a result of the organic layer grafting depicted by the number of bars.

FIG. 11 depicts a current-voltage (I-V) characteristics of Si NW solar cells with and without grafted molecules DMSO and ethylene glycol under AM1.5 illumination.

FIG. 12 depicts an XPS analysis of two surfaces: one is after a post etching process and the other is without said post etching, but after only having the pre-etching surface treatment. The stability measurement corresponds to the amount of hydrogen bonds detected on the silicon surface.

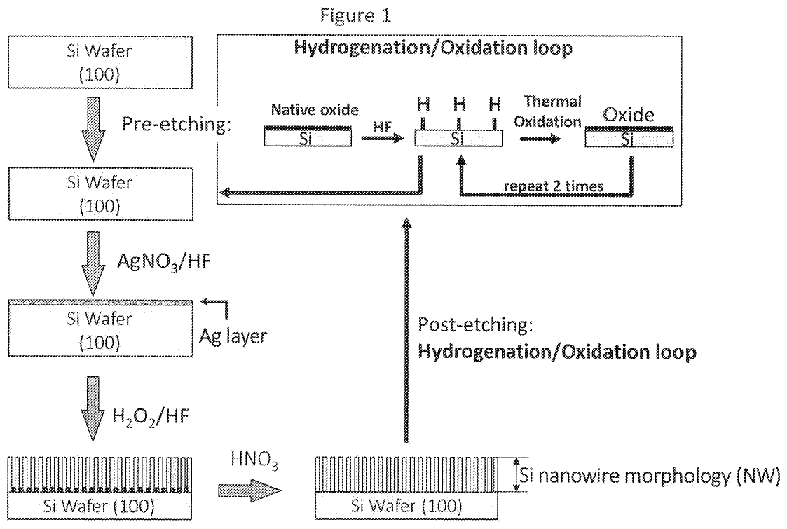

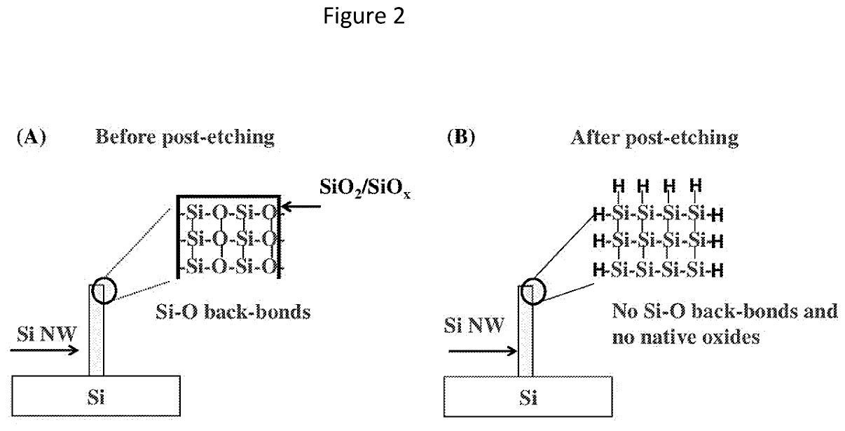

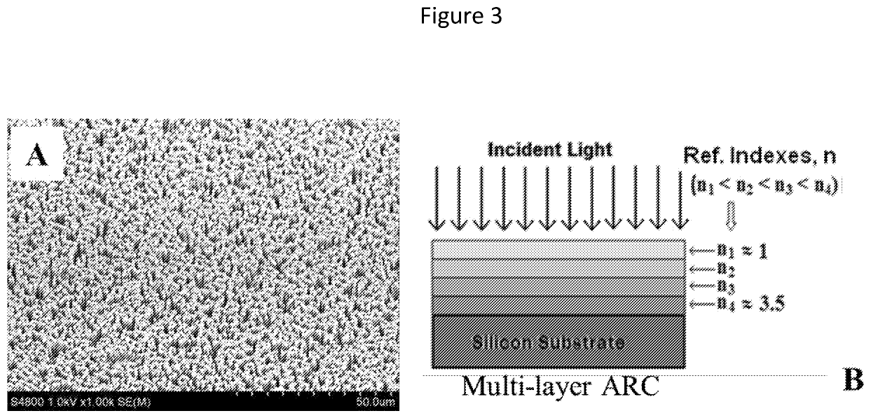

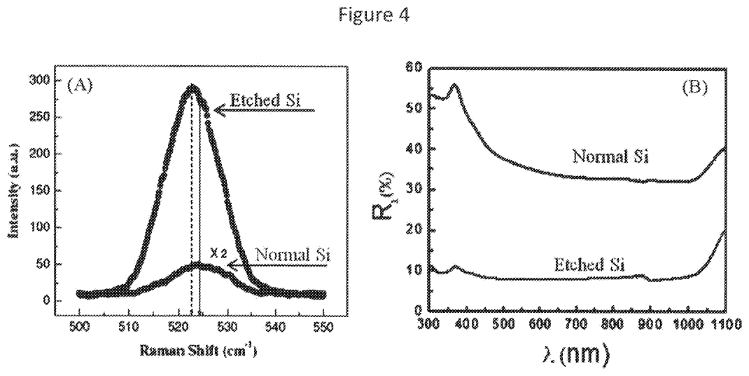

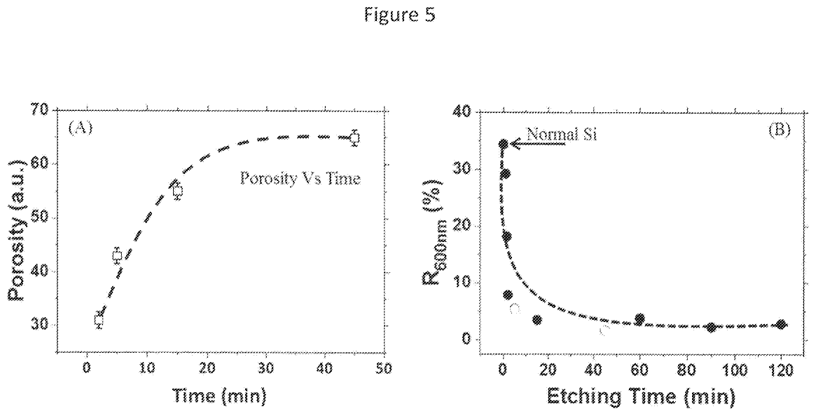

### EXAMPLES

### Nano-Reactor

A nano-reactor that can maintain constant high temperatures (up to 500° C.) and pressures (up to 350 bars) was utilized. In addition, the nano-reactor is also fully programmed at a high resolution of time durations (in the scale of seconds), pressure steps (100 bars in 1 min), and temperature steps (100° C. in 1 min) to generate shock-waves. The extreme conditions are important to overcome the Van-Der-Waals interaction (while preserving the etched morphology of the Si) and to obtain a full molecular coverage regardless to the molecular steric effect.

### Example 1—Surface Treatment to Remove Silicon Oxide (Si—O Bonds)/Pre-Etching and Post Etching

Silicon substrates (wafers) of both Si (100) and Si (111) were cleaned by washing with isopropanol and drying under N₂ (g) for 10 s. Then, the samples were sonicated with isopropanol for 30 s under 40 Hz and dried under N₂ (g) for 10 s. The obtained Si samples were immersed in buffered HF solution (pH=6) for 30 s and then moved into a solution of 70 wt % NH₄F for 30 s. The samples were then rinsed in DI water (18 MΩ·cm) for <10 s to limit oxidation and dried in flowing N₂ (g) for 10 s. The Si samples were thermally oxidized in O₂ with 30% humidity at 500° C. for 5 min in order to achieve fully oxidizes Si surface. Then the obtained Si samples were immersed again in buffered HF solution (pH=6) for 30 s and moved into a solution of 70 wt % NH₄F and later vacuumed under 10⁻⁶ torr for 10 min to remove (as much as possible) the remaining of the solvent residuals.

### Example 2—Surface Etching

### A) Silicon Surface Etching Procedure

Ag nanoparticles were deposited on the hydrogenated Si wafer surface obtained from Example 1 by immersing the Si wafer in aqueous solution of 0.02 M silver nitrate (AgNO₃) and 5 M HF in a volume ratio 1:1 (solution I) for 20 s. In the second step, the Si wafer was immersed in a 50 mL solution containing 5 M HF and 30% H₂O₂ in the volume ratio 10:1 (solution II) in a Teflon vessel for 20 min at room temperature. Next, the surfaces obtained after the etching procedure with solution I and II were rinsed several times in deionized water and dried at room temperature. Finally, the whole wafer was washed in a concentrated (65%) nitric acid (HNO₃) for 15 min to remove residual Ag nanoparticles from the Si NW surfaces. The post etching process including the Si surfaces' hydrogenation, oxidization in 500 degrees and re hydrogenation took place as described in Example 1.

### B) Silicon Surface Preparation—Effect of Duration of Exposure to Acid

In order to study the influence of the acid exposure duration on the growth of the silicon NW (in solution II), phosphorous doped i.e. n-type (N_{D}=10¹⁴ #P atoms·cm⁻³, 10-50 Ω·cm) silicon (Si) wafers with <100> crystal orientations were used. Prior to etching, the Si [0.5 cm×0.5 cm] samples were cleaned in acetone, isopropyl alcohol (IPA), deionized water (DI), and piranha solution (H₂SO₄:H₂O₂=3:1) respectively for 10 min, followed by thorough rinsing in DI water. Finally, the wafer was dipped in 10M Hydrofluoric acid (HF) for 10 min to remove the native oxide layer.

Nest, silver (Ag) nano-particles were deposited on the Si wafer surface by immersing the silicon surface in an aqueous solution consisting of 5M HF and Silver nitrate (AgNO₃) 20 mM in 1:1 volume ratio (solution I) for 20 s. Then, the silicon wafer was immersed in a solution containing 2% HF (10 mL) and 30% H₂O₂ (2 mL) and DI water (18 mL) (solution II), in a Teflon dish at room temperature. The immersion time was varied from 5 to 3840 seconds in order to follow the growth of nanowires with time.

The etching process is quenched (after fixed time) by immediately dipping the wafer in a concentrated (65%) nitric acid (HNO₃) for 15 min to remove residual Ag nanoparticles which induce the selective etching process of the Si NWs. Each silicon wafer surface obtained after the etching was rinsed thoroughly in DI water several times and dried in air.

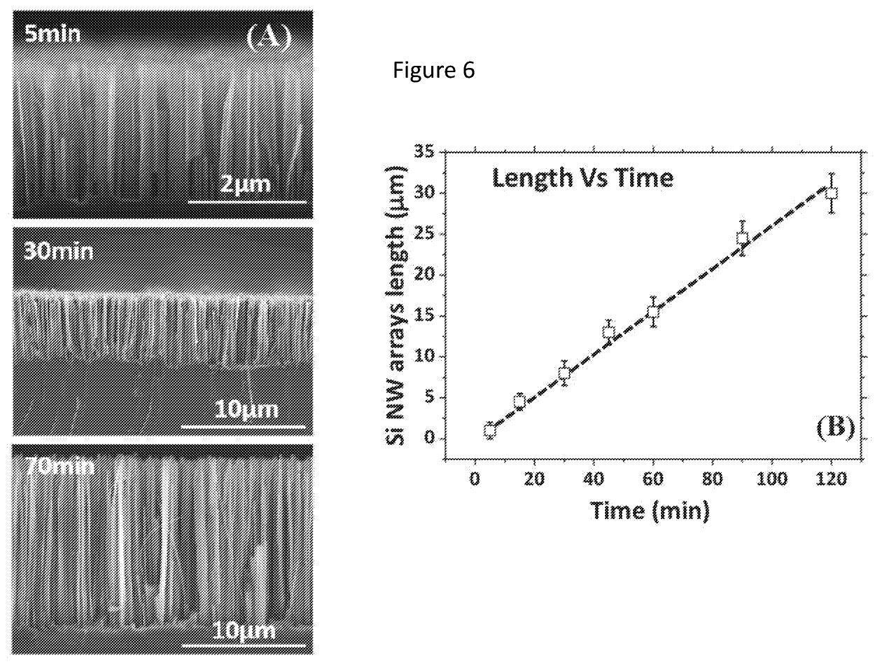

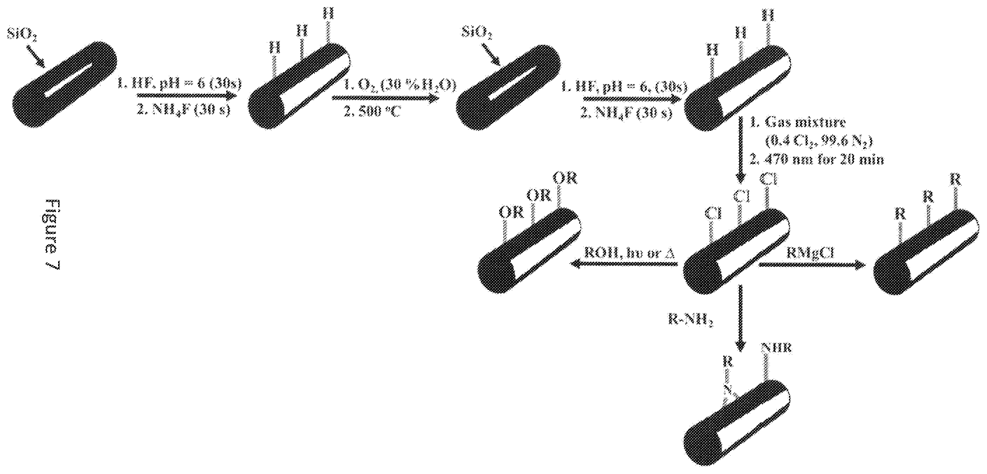

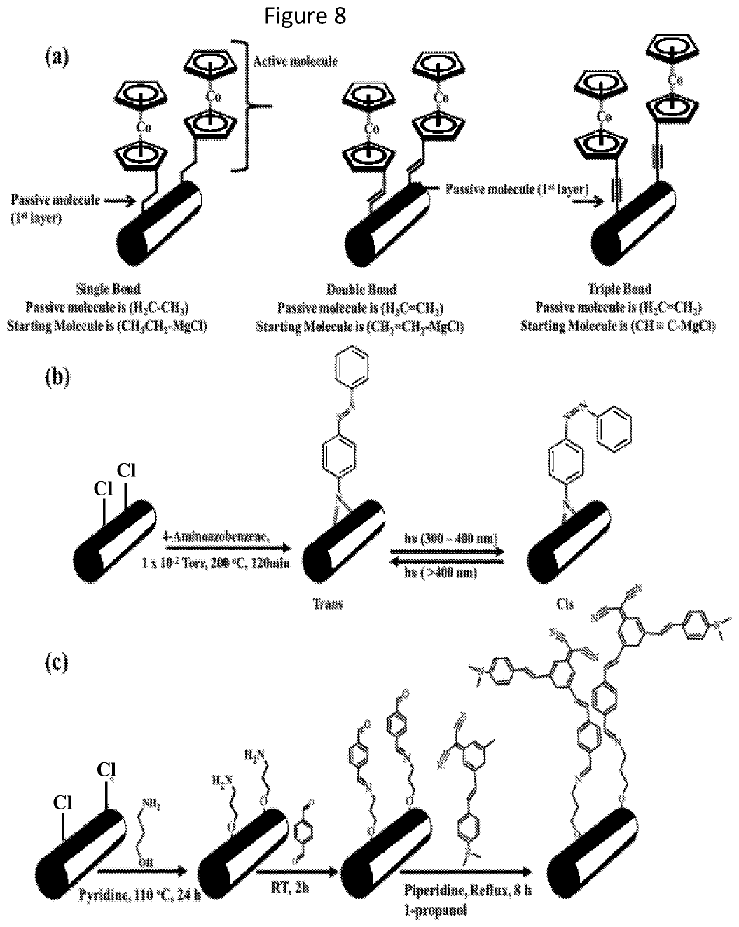

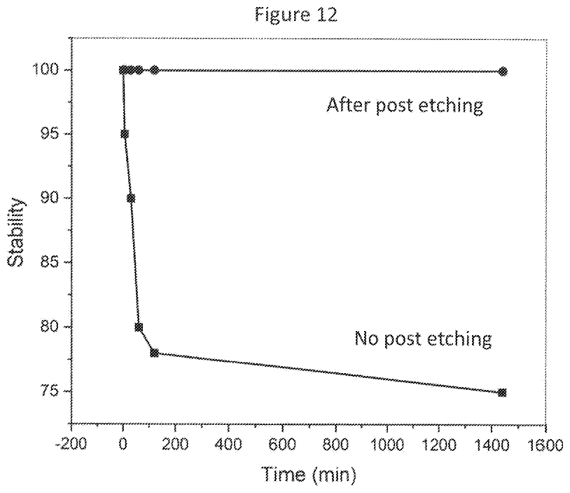

The surface treatment as described above in Example 1 was repeated before further sample processing in order to obtain stable hydrogen bonds. To this end, the stability of the hydrogen surface bonds was studied by measuring the rate of surface oxidation upon exposure to ambient conditions. XPS analysis was performed at different times on two surfaces—one after post etching and one which was not exposed to post etching process, but only after the pre-etching process. The Si2p XPS pick was followed to track the formation of silicon oxide on the surface. It was surprisingly found that after the post etching process, the hydrogen bonds formed on the silicon surface may remain stable for 2 days, while without performing said process, the Si—H bonds start tend to oxidize rapidly after about five minutes as can be seen in FIG. 12. SEM images with a corresponding graph depicting the correlation between the exposure time to acid and the elongation of the nanowires with time is presented in FIG. 6.

The surface etching detailed above was used for both kinds of Si wafers (100) and (111).

### Example 3—Surface Chlorination

The freshly etched Si surface was placed under a stream of chlorine gas mixture (0.4% Cl₂ and 99.6% N₂) and illuminated under soft blue light (470 nm) for 20 minutes to form defect free Cl-terminated Si surfaces. The obtained surface was then rinsed with N₂ flow.

### Example 4—Surface Alkylation

First layer (passive) deposition procedures: the connection of the passive layer to the silicon surface was carried out as a covalent attachment.

A) 1 μl of butyl Grignard solution R—MgCl, [R═CH₃(CH₂)₂] 0.5M, was placed on the Si sample inside a nano-reactor under inert atmosphere. The reaction took place for 2 hours at 10 bars and 100° C. The Si sample was removed from the nano-reactor, rinsed in THF and later with methanol, and dried under a stream of N₂(g), and kept under vacuum (10⁻⁶ torr) for 30 minutes. The resulted sample was characterized to have full coverage utilizing XPS.

B) Surface methylation: a hydrogenated Si substrate was exposed to radiation of hv=450 nm for to 1 minute under nitrogen atmosphere. Gas mixture of 99.6% of H₂ and 0.4 Cl₂ was introduced to the reactor. After this, methyl (CH₃) was grafted onto the silicon surface utilizing a drop cast of CH₃MgCl solution in THF. The concentration of the CH₃MgCl solution was 0.5M and the volume of 1 microliter. After that, a shock wave of 5 atm for 5 minutes was applied.

Second Layer (Active) Deposition Procedure:

1) Ethylene Glycol (p-Type Active Molecule):

An active layer of ethylene glycol was deposited to obtain physical adsorption via drop casting from 10 microliter ethylene glycol solution of concentration 0.1M on the CH₃ layer obtained according to the surface methylation described above. The surface having the ethylene glycol on its surface was then exposed to shock wave of 5 atm for 5 min under nitrogen. After this, the sample was taken out and rinsed with N₂ gun for 1 minute.

2) Dimethyl Sulfoxide (DMSO) (p-Type Active Molecule):

The active layer DMSO was deposited via drop casting to obtain physical adsorption, utilizing a 10 microliter DMSO solution of concentration 0.1M on the CH₃ layer obtained according to the surface methylation described above. The silicon having the DMSO on its surface was then exposed to shock wave of 5 atm for 5 min under nitrogen. After this, the sample was taken out and rinsed with N₂ gun for 1 minute.

Characterization of Silicon Surface After Organic Layers Grafting

X-ray photoelectron spectroscopy (XPS) analysis was obtained utilizing the XPS of thermofisher. Core level spectra were excited by monochromatic Al Kα radiation (1487 eV), and photoelectrons were picked up at a takeoff angle of 35° enhancing the surface sensitivity of the technique to about 10-15 Å depth. Scan times of up to ˜1 h were employed for all data collections. Data analysis and precise binding energy positions, fwhm, and areas were calculated by peak fitting using the XPS Thermofisher advantage software. Peak fitting solutions were sought for χ²<1, where χ² stands for the standard deviation.

A. First experiment was done in order to compare a silicon surface before any treatment “as is”, a silicon surface that was treated according to the pre-etching procedure and a silicon substrate having the organic molecules grafted onto its surface as described above.

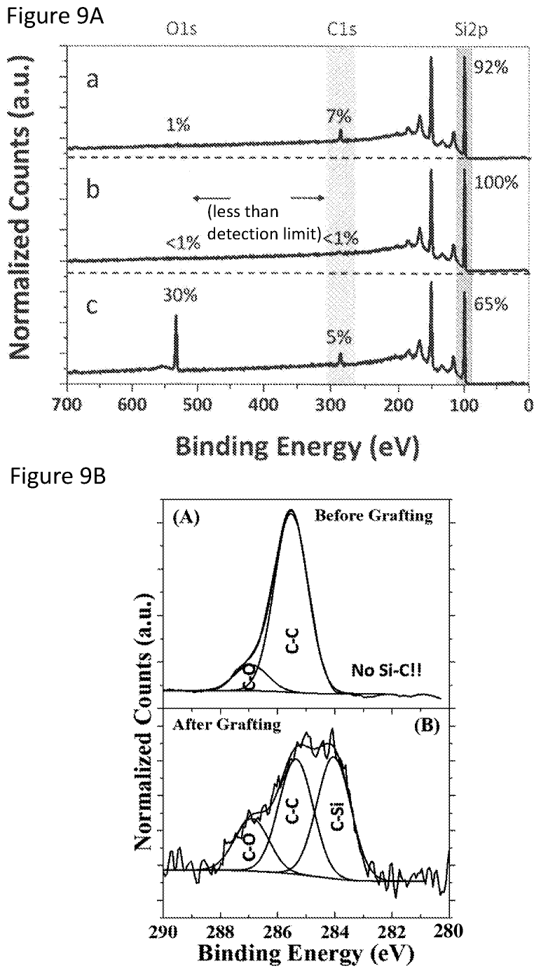

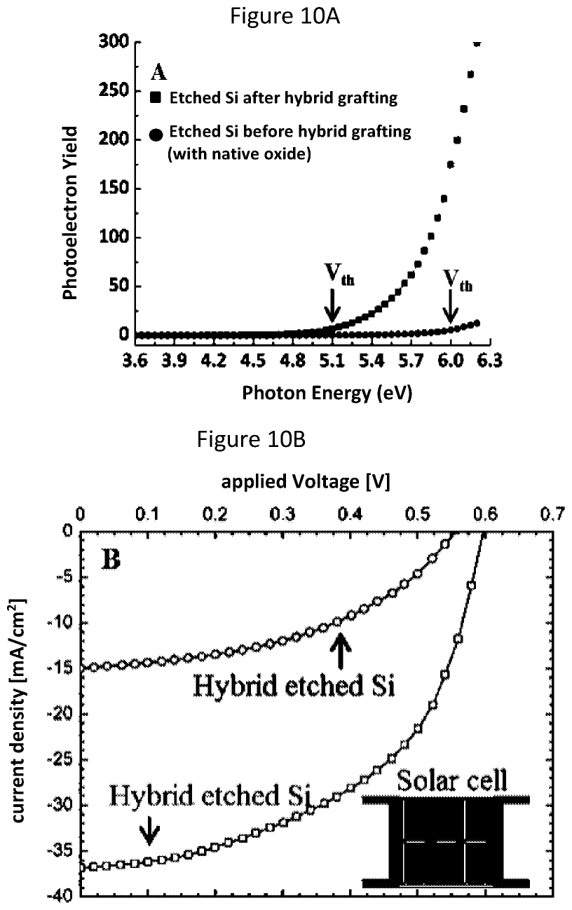

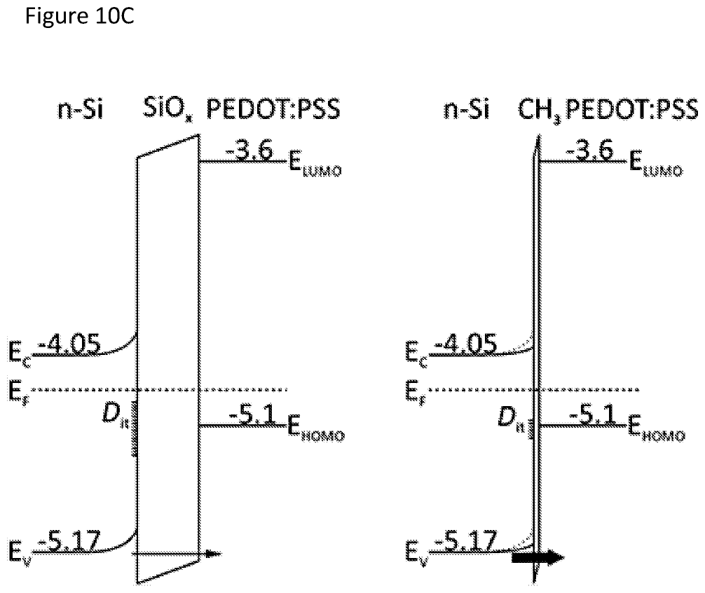

As can be seen in FIG. 9A, the XPS depicted three main peaks named O1s, C1s and Si2p. The Si2p represents the silicon surface while C1s and O1s represent the organic moieties. With regards to Si2p peaks, it can be seen that after pre-etching this signal is the greatest since the silicon was clean and did not contain any further molecules onto its surface. After the organic layer deposition the silicon signal is lowered and an additional carbon signal which relates to the organic compounds is depicted. It should be further noted that the organic contamination on the surface of the silicon which was not cleaned (“as is”) was very high. According to the results, said carbon based contamination was completely removed by the pre-etching procedure.

B. A second experiment was carried out in order to compare the chemical nature of the attachment between the organic compounds that were found on the not-treated silicon surface (contaminations) and the organic compounds that were grafter to the silicon surface utilizing the procedure described above. Signal C1s was de-convoluted and the results are presented in FIG. 9B. According to graph A, there are no Si—C bonds in the sample before the treatment (and before the grafting) and therefore, the organic contamination was not covalently bonded to the silicon surface. In contrast, a clear peak attributed to Si—C bonds was depicted in the case of the silicon surface after the organic molecules grafting procedure (graph B), proving the successful covalent functionalization of the silicon surface.

### Example 5—Preparation of a Device—a Solar Cell Based on Molecule-Si Junction

Hybrid solar cells were prepared from n-type (100) phosphorus-doped Si wafers with a conductivity of 0.1-0.5 Ω·cm. Samples (14.7×14.7 mm²) were cleaned in acetone, isopropanol, and H₂O in an ultrasonic bath for 5 min and etched in 5% hydrofluoric acid (HF) for 2 min to remove the native silicon oxide and to passivate the surface with hydrogen by Si—H bonds. An Ohmic Si back contact was fabricated, by e-beam evaporation of 40 nm Ti and 100 nm Au contact, followed by an annealing step at 850° C. for 1 hour. The samples were treated as explained in Examples 1-4 and were characterized by having the NW morphology of the invention coated with the organic molecules according to the exemplified procedure above. One sample of etched silicon surface functionalized with DMSO and one sample of etched silicon surface functionalized with ethylene glycol were utilized to construct solar cell. The samples were re heated up to 130 ° C. on a hot plate for 30 seconds to improve the wetting and structural properties of the molecule layer. A gold (Au) grid having a thickness of 50 nm was evaporated as a front electrode utilizing a shadow mask defining solar cells with an active area of 38.5 mm². The evaporation was carried out utilizing E-beam evaporator (model BAK-501A), and was performed using metal evaporator with an acceleration voltage of 30 kV. The obtained solar cells were characterized by current—voltage (I-V) measurements using an AM 1.5 solar spectrum (Newport solar simulator) for illumination.

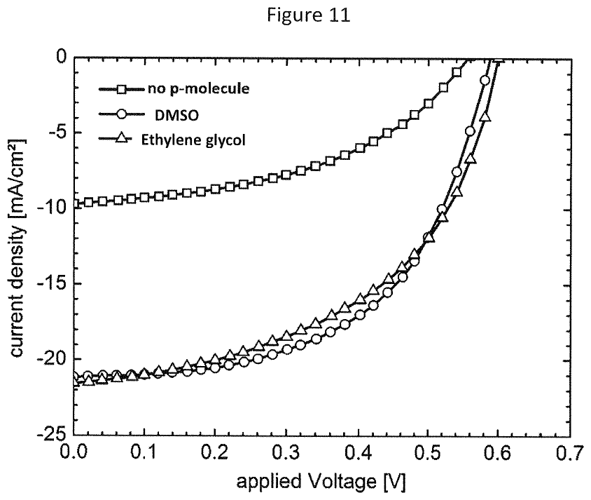

Results: FIG. 11 depicts the current-voltage (I-V) characteristics of ethylene glycol-based and DMSO-based solar cells under AM 1.5 illumination. On a bear silicon surface having no organic layer grafter thereon, the sample obeys a short circuit current (Jsc) of 10 mA/cm², an open circuit voltage (Voc) of 570 mV and a conversion efficiency (η) of 2.7%. Upon achieving the grafted molecules layer, the measurement depicts improved performance with values for Jsc, Voc, η of 22.0 mA/cm², 600 mV, 8%, respectively. The low values of Jsc in intrinsic solar cell is attributed to high contact resistances (Rs 300Ω).

1. A method for preparing a silicon hybrid interface structure comprising the following steps:
a) Providing an etched Si substrate having Si—H bonds on the surface;
b) Exposing the silicon surface of step (a) to chlorine containing gas while illuminating the surface with light; and
c) Treating the Si substrate of step (b) with one or more organic reactant(s) to produce a first organic layer which is covalently bonded to the silicon surface.

2. The method of claim 1, wherein the Si substrate provided in step (a) is an etched silicon substrate characterized in having a nanowire (NW) morphology.

3. The method of claim 1, wherein the substrate of step (a) is provided by an etching procedure comprising the steps of: subjecting an H-terminated Si surface to a solution comprising an oxidizable aggregation agent and an acid, oxidizing the surface to remove aggregated material formed on the Si substrate and washing the surface.

4. The method of claim 3, wherein said oxidizable aggregation agent is selected from the group consisting of silver nitrate (AgNO₃), chloroauric acid (HAuCl₄), silver acetate (AgCO₂CH₃), silver benzoate (AgCO₂C₆H₅), Iron(II) acetate, Iron(III) chloride, Fe(NO₃)₃, Ag (s), Au (s), Pt (s), Cr(s) and tetramethylammonium hydroxide.

5. The method of claim 4, wherein said oxidizable aggregation agent is silver nitrate (AgNO₃) dissolved in HF solution.

6. The method of claim 3, wherein said oxidation of the aggregation agent is achieved by utilizing H₂O₂ and HF mixture.

7. The method of claim 3, wherein said washing is carried out by utilizing nitric acid.

8. The method of claim 3, wherein the etching procedure is preceded by and followed by a surface treatment comprising the steps of a) removal of Si-oxide layer with the aid of HF/NH₄F solution, b) thermally growing a fresh Si-oxide layer and c) removal of said freshly grown Si-oxide layer to obtain H-terminated Si surface.

9. The method of claim 1, wherein the illumination of step (b) is of an intensity range of about 1 mW to about 5 mW and wavelength of between about 400 nm to about 550 nm.

10. The method of claim 1, wherein the organic reactants for the first organic layer of step (c) are selected from the group consisting of amine, alcohol, halide and alkylating reagent.

11. The method of claim 1, wherein the reactants of step (c) are characterized in having at least one functional group, such that said group reacts with the Si surface atom/s.

12. The method of claim 1, further comprising the step of reacting the Si surface having the first organic layer thereon with a second organic reactant to provide a second layer, said second organic layer being either covalently bound or physically adsorbed to the first organic layer.

13. The method of claim 12, wherein the second organic layer comprises functional electrical molecules selected from n-type molecules and p-type molecules, optically active molecules and combination thereof.

14. A method for the preparation of etched silicon substrate having nanowires morphology comprising the steps of: (a) providing a hydrogen terminated silicon substrate; (b) exposing the substrate obtained in step (a) to an oxidizable aggregation agent and an acid; (c) oxidizing the surface to remove aggregated material formed on the Si substrate; and (d) washing the silicon substrate obtained in step (c).

15. The method of claim 14, wherein said oxidizable aggregation agent is selected from the group consisting of silver nitrate (AgNO₃), chloroauric acid (HAuCl₄), silver acetate (AgCO₂CH₃), silver benzoate (AgCO₂C₆H₅), Iron(II) acetate, Iron(III) chloride, Fe(NO₃)₃, Ag (s), Au (s), Pt (s), Cr(s) and tetramethylammonium hydroxide.

16. The method of claim 15, wherein said oxidizable aggregation agent is silver nitrate (AgNO₃) dissolved in HF solution.

17. The method of claim 14, wherein said oxidation of the aggregation agent is achieved by utilizing H₂O₂ and HF mixture.

18. The method of claim 14, wherein said washing is carried out by utilizing nitric acid.

19. The method of claims 14, wherein the etching procedure is preceded by and followed by a surface treatment comprising the steps of a) removal of Si-oxide layer with the aid of HF/NH₄F solution, b) thermally growing a fresh Si-oxide layer and c) removal of said freshly grown Si-oxide layer to obtain H-terminated Si surface.

20. A device for converting radiation to electrical energy having a hybrid interface structure, said hybrid interface structure is prepared according to claim 1.

21. A device for converting radiation to electrical energy having a hybrid interface structure comprising:
i) An etched Si substrate; and
ii) An organic layer;
wherein said etched Si substrate surface is coated with said organic layer, and wherein said etched Si substrate is substantially free of Si—O bonds.

22. The device according to claim 21, wherein the Si substrate is a thin layer Si substrate or of an unpure Si source.

23. The device according to claim 21, wherein the organic layer is chemically bound to the etched Si surface, and wherein said layer is between about 2.5 Å to about 50 Å in thickness.

24. The device according to claims 21, wherein said organic layer comprises a top organic layer which is physically adsorbed to a bottom organic layer, said bottom organic layer is covalently bound to the Si substrate.

25. The organic layer of claim 21, wherein the organic layer comprises functional electrical molecules selected from n-type molecules and p-type molecules, optically active molecules and combination thereof.
